(19) United States
(12) Patent Application Publication
(10) Pub. No.: US 2024/0241438 A1
(43) Pub. Date: Jul. 18, 2024

(54) PHOTORESIST COMPOSITION AND METHOD OF MANUFACTURING INTEGRATED CIRCUIT DEVICE BY USING THE SAME

(71) Applicant: SAMSUNG ELECTRONICS CO., LTD., Suwon-si (KR)

(72) Inventors: Sung Hwan PARK, Suwon-si (KR); Hyun-Ji Song, Suwon-si (KR); Juhyeon Park, Suwon-si (KR); Sungmin Ko, Suwon-si (KR); Sounghyun Jun, Suwon-si (KR)

(21) Appl. No.: 18/403,927

(22) Filed: Jan. 4, 2024

(30) Foreign Application Priority Data
Jan. 17, 2023 (KR) 10-2023-0006989

(51) Int. Cl. G03F 7/004; G03F 7/039

(52) U.S. Cl. CPC G03F 7/0045; G03F 7/039

(57) ABSTRACT

A photoresist composition that includes a photosensitive polymer that can be cut by a chain scission mechanism due to light, a radical quencher including a phenol-based compound, and a photoactive compound (PAC) are provided.

### CROSS-REFERENCE TO RELATED APPLICATION

This application is based on and claims priority under 35 U.S.C. § 119 to Korean Patent Application No. 10-2023-0006989, filed on Jan. 17, 2023, in the Korean Intellectual Property Office, the disclosure of which is incorporated by reference herein in its entirety.

### BACKGROUND

### 1. Field

Embodiments relate to a photoresist composition and a method of manufacturing an integrated circuit device by using the photoresist composition. More particularly, embodiments relate to a photoresist composition that includes a chain scission polymer, and a method of manufacturing an integrated circuit device by using the photoresist composition.

### 2. Description of the Related Art

Due to the advance of electronics technology, semiconductor devices have been rapidly scaled down in size in recent years. Therefore, photolithography processes having an advantage in implementing fine patterns are desired. In particular, there is demand for a photoresist composition that is capable of improving sensitivity and a critical dimension (CD) distribution while ensuring excellent etch resistance and resolution in a photolithography process of manufacturing an integrated circuit device.

### SUMMARY

Embodiments are directed to a photoresist composition including a photosensitive polymer that can be cut by a chain scission mechanism due to light, a radical quencher including a phenol-based compound, and a photoactive compound (PAC).

Embodiments may further include a photosensitive polymer to be cut by a chain scission mechanism due to light, a radical quencher including an amine-based compound, and a photoacid generator

Embodiments may also include a method of manufacturing an integrated circuit device, the method including forming a photoresist film on a lower film by using a photoresist composition that includes a photosensitive polymer, a radical quencher, and a photoactive compound (PAC); exposing a first region, which is a portion of the photoresist film, to light to generate acid or base from the PAC in the first region, to deactivate the radical quencher by using the acid or the base, and to cut the photosensitive polymer in the first region by a chain scission mechanism; forming a photoresist pattern by developing the photoresist film, the photoresist pattern including a second region that is a non-exposed portion of the photoresist film; and processing the lower film by using the photoresist pattern

### BRIEF DESCRIPTION OF THE DRAWINGS

Features will become apparent to those of skill in the art by describing in detail exemplary embodiments with reference to the attached drawings in which:

FIG. 1 is a flowchart illustrating a method of manufacturing an integrated circuit device, according to an embodiment; and

FIGS. 2A to 2E are cross-sectional views respectively illustrating operations of a method of manufacturing an integrated circuit device, according to an embodiment.

### DETAILED DESCRIPTION

Hereinafter, embodiments will be described in detail with reference to the accompanying drawings. Like components are denoted by like reference numerals throughout the specification, and repeated descriptions thereof are omitted.

A photoresist composition according to an embodiment may include a photosensitive polymer, a radical quencher, and a photoactive compound (PAC).

In an embodiment, the photosensitive polymer may include a photosensitive polymer that can be cut by a chain scission mechanism due to exposure to light. In an embodiment, the photosensitive polymer may include a homopolymer including a single monomer. For example, the single monomer may be an acrylate-based monomer. In an embodiment, the photosensitive polymer may include a copolymer including two or more monomers. For example, the two or more monomers may each independently include one selected from an acrylate-based monomer and a styrene-based monomer. The photosensitive polymer may include, for example, polymethylmethacrylate (PMMA), or a copolymer of α-chloromethacrylate and α-methylstyrene. In the photoresist composition according to an embodiment, the photosensitive polymer may be present in an amount of about 0.1 wt % to about 90 wt % based on the total weight of the photoresist composition. When the amount of the photosensitive polymer in the photoresist composition is too high or too low, the storage stability of the photoresist composition could deteriorate, or there may be a deterioration in a capability for the photoresist composition to form a photoresist film.

In the photoresist composition according to an embodiment, the radical quencher may include a phenol-based compound or an amine-based compound. In an embodiment, the radical quencher including a phenol-based compound may be represented by Formula 1.

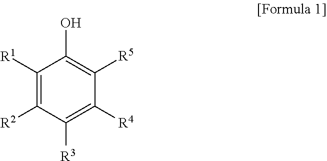

In Formula 1, R¹ to R⁵ are each independently a hydrogen atom, a hydroxyl group, a C1 to C10 alkyl group, a C1 to C10 alkenyl group, a C1 to C10 alkynyl group, a C6 to C18 aryl group, or a C6 to C18 arylalkyl group Two adjacent groups selected from R¹ to R⁵ may be connected to each other to form a ring.

In an embodiment, the radical quencher including a phenol-based compound may include an electron-donating group. For example, the radical quencher including a phenol-based compound may include at least one electron-donating group selected from an alkyl group, an alkenyl group, an alkynyl group, an aryl group, and an arylalkyl group, as non-limiting examples The radical quencher including a phenol-based compound may not include an electron-donating group.

In an embodiment, the radical quencher may include a monophenol compound. As examples, the radical quencher may be selected from phenol, ortho-cresol, meta-cresol, para-cresol, ortho-chlorophenol, meta-chlorophenol, para-chlorophenol, 2-hydroxybenzoic acid, 3-hydroxybenzoic acid, 4-hydroxybenzoic acid, 4-vinylphenol, 4-ethylphenol, 4-isopropylphenol, 4-isobutylphenol, and para-coumaric acid, as non-limiting examples.

In an embodiment, the radical quencher may include a polyphenol compound. For example, the radical quencher may be selected from resorcinol (1,3-dihydroxybenzene), phloroglucinol (benzene-1,3,5-triol), 2,2′,4,4′-tetrahydroxydiphenyl sulfide, and 2,2′,4,4′-tetrahydroxybenzophenone, as non-limiting examples.

In an embodiment, the radical quencher may include, as non-limiting examples, at least one selected from the following phenol compounds. In the following formulae, Me refers to a methyl group.

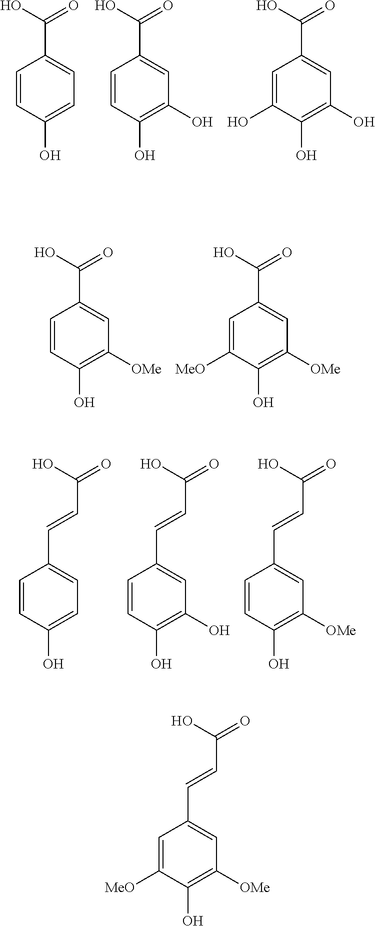

In an embodiment, the radical quencher may include a phenol-based monomer.

In an embodiment, the radical quencher including an amine-based compound may be represented by Formula 2.

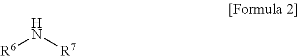

In Formula 2, R⁶ and R⁷ may each independently be a C6 to C18 aryl group or a C6 to C18 arylalkyl group.

In an embodiment, the radical quencher including an amine-based compound may include an electron-donating group. For example, the radical quencher including an amine-based compound may include at least one electron-donating group selected from an aryl group and an arylalkyl group, as non-limiting examples. The radical quencher including an amine-based compound may not include an electron-donating group.

In an embodiment, the radical quencher may include an amine-based monomer.

A single radical quencher or a combination of two or more radical quenchers may be used as the radical quencher in the photoresist composition. The radical quencher may be present in an amount of about 5 wt % to about 50 wt % based on the total weight of the photosensitive polymer. When the amount of the radical quencher in the photoresist composition is too low or too high, the amount may be insufficient for the radical quencher to increase the difference in solubility in a developer between the exposed region and the non-exposed region of the photoresist film.

In the photoresist composition according to an embodiment, the PAC may undergo decomposition of the chemical structure thereof by absorbing active energy rays through light irradiation thereon, thereby generating acid or base. In an embodiment, the PAC may include one selected from a photobase generator and a photoacid generator. Specifically, when the radical quencher includes a phenol-based compound, the PAC may include one of a photobase generator and a photoacid generator, and when the radical quencher includes an amine-based compound, the PAC may include a photoacid generator.

When the PAC includes a photobase generator, a material constituting the photobase generator is not particularly limited so long as the material generates a base through light irradiation thereon. In an embodiment, the photobase generator may include a nonionic photobase generator. In an embodiment, the photobase generator may include an ionic photobase generator. The base generated from the photobase generator due to light irradiation may cause the radical quencher to be in a deprotonated state due to an acid-base reaction with the radical quencher in the exposed region of the photoresist film obtained from the photoresist composition according to an embodiment, thereby deactivating the radical quencher.

In an embodiment, the photobase generator may include a carbamate compound, an α-aminoketone compound, a quaternary ammonium compound, an aminocyclopropenone compound, an O-acyloxime compound, or a 2-(9-oxoxanthen-2-yl) propionic acid 1,5,7-triazabicyclo[4.4.0]dec-5-ene salt.

Examples of the photobase generator including a carbamate compound may include 1-(2-anthraquinonyl)ethyl 1-piperidinecarboxylate, 1-(2-anthraquinonyl)ethyl 1H-2-ethylimidazole-1-carboxylate, 9-anthrylmethyl N,N-diethylcarbamate, 9-anthrylmethyl 1H-imidazole-1-carboxylate, bis[1-(2-anthraquinonyl)ethyl] 1,6-hexanediylbiscarbamate, bis(9-anthrylmethyl) 1,6-hexanediylbiscarbamate, and the like.

The photobase generator including a carbamate compound may be represented by, for example, Formula 3 or 4.

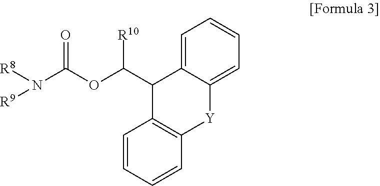

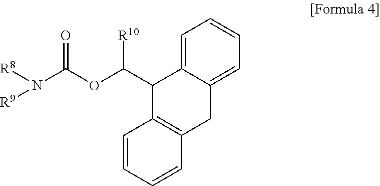

In Formulae 3 and 4, R⁸ is a C1 to C10 alkyl group, a C1 to C10 alkenyl group, a C1 to C10 alkynyl group, a C6 to C18 aryl group, or a C6 to C18 arylalkyl group, R′ and R¹⁰ may each independently be hydrogen, a C1 to C10 alkyl group, a C1 to C10 alkenyl group, a C1 to C10 alkynyl group, a C6 to C18 aryl group, or a C6 to C18 arylalkyl group, and Y is a heteroatom.

Examples of the photobase generator including an α-aminoketone compound may include 1-phenyl-2-(4-morpholinobenzoyl)-2-dimethylaminobutane, 2-(4-methylthiobenzoyl)-2-morpholinopropane, and the like.

Examples of the photobase generator including a quaternary ammonium compound may include 1-(4-phenylthiophenacyl)-(1-azonia-4-azabicyclo[2.2.2]octane) tetraphenylborate, 5-(4-phenylthiophenacyl)-1-aza-5-azoniabicyclo[4,3,0]-5-nonene tetraphenylborate, 8-(4-phenylthiophenacyl)-1-aza-8-azoniabicyclo[5,4,0]-7-undecene tetraphenylborate, and the like.

Examples of the photobase generator including an aminocyclopropenone compound may include 2-diethylamino-3-phenylcyclopropenone, 2-diethylamino-3-(1-naphthyl)cyclopropenone, 2-pyrrolidinyl-3-phenylcyclopropenone, 2-imidazolyl-3-phenylcyclopropenone, 2-isopropylamino-3-phenylcyclopropenone, and the like.

Examples of the photobase generator including an O-acyloxime compound may include 1,2-octanedione, 2-dimethylamino-2-(4-methylbenzyl)-1-(4-morpholin-4-yl-phenyl)-butan-1-one, 1-(4-phenylsulfanylphenyl)-butane-1,2-dione 2-oxime-O-benzoate, 1-(4-phenylsulfanylphenyl)-octane-1,2-dione 2-oxime-O-benzoate, 1-(4-phenylsulfanylphenyl)-octan-1-one oxime-O-acetate, 1-(4-phenylsulfanylphenyl)-butan-1-one oxime-O-acetate, and the like.

In an embodiment, the photobase generator may be represented by Formula 5.

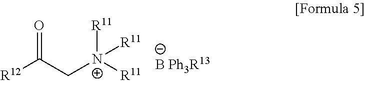

In Formula 5, R¹¹ and R¹³ are each independently a C1 to C10 alkyl group, a C1 to C10 alkenyl group, a C1 to C10 alkynyl group, a C6 to C18 aryl group, or a C6 to C18 arylalkyl group, and R¹² is a C6 to C18 aryl group.

In an embodiment, the photobase generator may include an ammonium salt.

In an embodiment, the photobase generator may include at least one selected from the following compounds, as non-limiting examples.

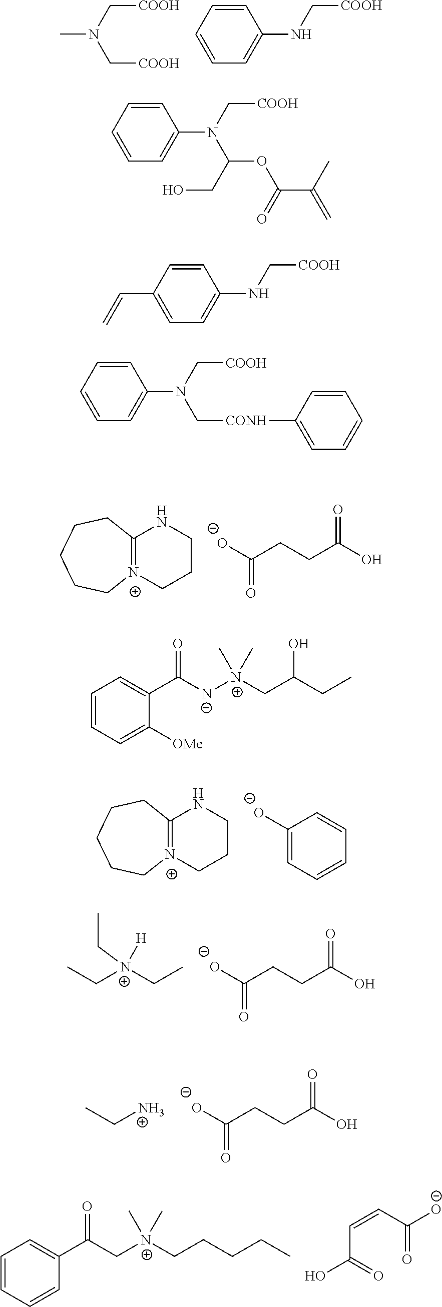

In an embodiment, the photobase generator may include at least one selected from the following ammonio groups, as non-limiting examples.

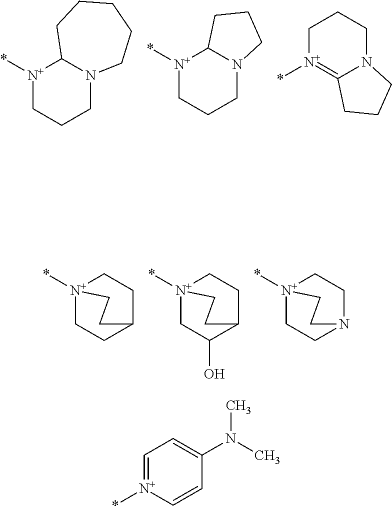

In the above formulae, * represents a binding site.

In an embodiment, the photobase generator may be selected from 5-benzyl-1,5-diazabicyclo[4.3.0]nonane, 5-(anthracen-9-yl-methyl)-1,5-diaza[4.3.0]nonane, 5-(2′-nitrobenzyl)-1,5-diazabicyclo[4.3.0]nonane, 5-(4′-cyanobenzyl)-1,5-diazabicyclo[4.3.0]nonane, 5-(3′-cyanobenzyl)-1,5-diazabicyclo[4.3.0]nonane, 5-(anthraquinon-2-yl-methyl)-1,5-diaza[4.3.0]nonane, 5-(2′-chlorobenzyl)-1,5-diazabicyclo[4.3.0]nonane, 5-(4′-methylbenzyl)-1,5-diazabicyclo[4.3.0]nonane, 5-(2′, 4′, 6′-trimethylbenzyl)-1,5-diazabicyclo[4.3.0]nonane, 5-(4′-ethenylbenzyl)-1,5-diazabicyclo[4.3.0]nonane, 5-(3′-trimethylbenzyl)-1,5-diazabicyclo[4.3.0]nonane, 5-(2′,3′-dichlorobenzyl)-1,5-diazabicyclo[4.3.0]nonane, 5-(naphth-2-yl-methyl-1,5-diazabicyclo[4.3.0]nonane, 1,4-bis(1,5-diazabicyclo[4.3.0]nonanylmethyl)benzene, 8-benzyl-1,8-diazabicyclo[5.4.0]undecane, 8-benzyl-6-methyl-1,8-diazabicyclo[5.4.0]undecane, 9-benzyl-1,9-diazabicyclo[6.4.0]dodecane, 10-benzyl-8-methyl-10-diazabicyclo[7.4.0]tridecane, 11-benzyl-1,11-diazabicyclo[8.4.0]tetradecane, 8-(2′-chlorobenzyl)-1,8-diazabicyclo[5.4.0]undecane, 8-(2′,6′-dichlorobenzyl)-1,8-diazabicyclo[5.4.0]undecane, 4-(diazabicyclo[4.3.0]nonanylmethyl)-1,1′-biphenyl, 4,4′-bis(diazabicyclo[4.3.0]nonanylmethyl)-11′-biphenyl, 5-benzyl-2-methyl-1,5-diazabicyclo[4.3.0]nonane, 5-benzyl-7-methyl-1,5,7-triazabicyclo[4.4.0]decane, and/or a combination thereof.

When the PAC includes a photoacid generator, a material constituting the photoacid generator is not particularly limited so long as the material generates acid through light irradiation thereon. In an embodiment, the photoacid generator may include a nonionic photoacid generator. In an embodiment, the photoacid generator may include an ionic photoacid generator. For example, the photoacid generator may include sulfonium, iodonium, or a mixture thereof. The acid generated from the photoacid generator due to light irradiation may cause the radical quencher to be in a deprotonated state by an acid-base reaction with the radical quencher in the exposed region of the photoresist film obtained from the photoresist composition according to an embodiment, thereby deactivating the radical quencher.

For example, the photoacid generator may include, as non-limiting examples, triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

In the photoresist composition according to an embodiment, a single PAC or a mixture of two or more PACs may be used as the PAC. The PAC may be present in an amount of about 1 to about 1.5 times the amount of the radical quencher. When the amount of the PAC is too low, there may be a deterioration in a capability for the PAC to deactivate the radical quencher in the exposed region of the photoresist film obtained from the photoresist composition according to an embodiment, and it may be insufficient for the PAC to increase a difference in solubility in a developer between the exposed region and the non-exposed region of the photoresist film. When the amount of the PAC in the photoresist composition is too high, there may be a deterioration in a capability for the photoresist composition to form a photoresist film.

In an embodiment, the photoresist composition may include a solvent. The solvent may include an organic solvent. The organic solvent may include, but is not limited to, at least one selected from ethers, alcohols, glycol ethers, aromatic hydrocarbon compounds, ketones, and esters. For example, the organic solvent may include ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbion: MIBC), hexanol, 1-methoxy-2-propanol, 1-ethoxy-2-propanol, ethylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxypropionate, ethoxyethoxypropionate, or a combination thereof.

In the photoresist composition according to an embodiment, the solvent may be present in a balanced amount except for amounts of main components including the photosensitive compound, which is to be cut by a chain scission mechanism due to exposure to light, the radical quencher, and the PAC. In an embodiment, the solvent may be present in an amount of about 0.1 wt % to about 99.7 wt % based on the total weight of the photoresist composition.

In an embodiment, the photoresist composition may further include at least one selected from a surfactant, a dispersant, a moisture absorber, and a coupling agent.

The surfactant may improve the coating uniformity and wettability of the photoresist composition. In an embodiment, the surfactant may include, as non-limiting examples, a sulfuric acid ester salt, a sulfonic acid salt, phosphoric acid ester, soap, an amine salt, a quaternary ammonium salt, polyethylene glycol, an alkylphenol ethylene oxide adduct, polyhydric alcohol, a nitrogen-containing vinyl polymer, or a combination thereof. For example, the surfactant may include an alkylbenzene sulfonic acid salt, an alkylpyridinium salt, polyethylene glycol, or a quaternary ammonium salt. When the photoresist composition includes the surfactant, the surfactant may be present in an amount of about 0.001 wt % to about 3 wt % based on the total weight of the photoresist composition.

The dispersant may cause respective components constituting the photoresist composition to be uniformly dispersed in the photoresist composition. In an embodiment, the dispersant may include, as non-limiting examples, an epoxy resin, polyvinyl alcohol, polyvinyl butyral, polyvinylpyrrolidone, glucose, sodium dodecyl sulfate, sodium citrate, oleic acid, linoleic acid, or a combination thereof. When the photoresist composition includes the dispersant, the dispersant may be present in an amount of about 0.001 wt % to about 5 wt % based on the total weight of the photoresist composition.

The moisture absorber may prevent, or reduce the likelihood, of adverse effects due to water in the photoresist composition. For example, the moisture absorber may prevent a metal in the photoresist composition from being oxidized by water. In an embodiment, the moisture absorber may include, as non-limiting examples, polyoxyethylene nonylphenolether, polyethylene glycol, polypropylene glycol, polyacrylamide, or a combination thereof. When the photoresist composition includes the moisture absorber, the moisture absorber may be present in an amount of about 0.001 wt % to about 10 wt % based on the total weight of the photoresist composition.

The coupling agent may improve the adhesion of the photoresist composition to an underlying film when the photoresist composition is coated on the underlying film. In an embodiment, the coupling agent may include a silane coupling agent. The silane coupling agent may include, as non-limiting examples, vinyltrimethoxysilane, vinyltriethoxysilane, vinyltrichlorosilane, vinyltris(β-methoxyethoxy)silane, 3-methacryloxypropyltrimethoxysilane, 3-acryloxypropyltrimethoxysilane, p-styryltrimethoxysilane, 3-methacryloxypropylmethyldimethoxysilane, 3-methacryloxypropylmethyldiethoxysilane, or trimethoxy[3-(phenylamino)propyl]silane. When the photoresist composition includes the coupling agent, the coupling agent may be present in an amount of about 0.001 wt % to about 5 wt % based on the total weight of the photoresist composition.

In the photoresist composition according to an embodiment, when the solvent includes only an organic solvent, the photoresist composition may further include water. In this case, the water may be present in an amount of about 0.001 wt % to about 0.1 wt % in the photoresist composition.

As described above, the photoresist composition according to an embodiment may include the photosensitive polymer, the radical quencher including a phenol-based compound or an amine-based compound, and the PAC. Therefore, in the case where a photolithography process is performed by using the photoresist composition according to an embodiment, even when radicals generated by light exposure in the exposed region of the photoresist film obtained from the photoresist composition diffuse to be introduced into the non-exposed region of the photoresist film, the radicals introduced from the exposed region into the non-exposed region may be quenched by the radical quencher in the non-exposed region. The radical quencher in the exposed region may be deactivated by acid or base generated from the PAC due to light exposure. Therefore, the photosensitive polymer may be selectively cut by a chain scission mechanism only in the exposed region of the photoresist film and may not be cut in the non-exposed region of the photoresist film. Accordingly, a difference in solubility in a developer between the exposed region and the non-exposed region of the photoresist film may be increased, thereby increasing the contrast therebetween. Therefore, when an integrated circuit device is manufactured by using the photoresist composition according to an embodiment, a critical dimension (CD) distribution of a pattern may be prevented from deteriorating during a forming of the pattern that is required for the integrated circuit device, and thereby improving the dimensional accuracy of the pattern intended to be formed.

The photoresist composition according to an embodiment may be advantageously used to form a pattern having a relatively high aspect ratio. For example, the photoresist composition according to an embodiment may be advantageously used for a photolithography process for forming a pattern having a fine width selected from a range of about 5 nm to about 100 nm.

Next, a method of manufacturing an integrated circuit device by using the photoresist composition according to an embodiment is described using specific examples.

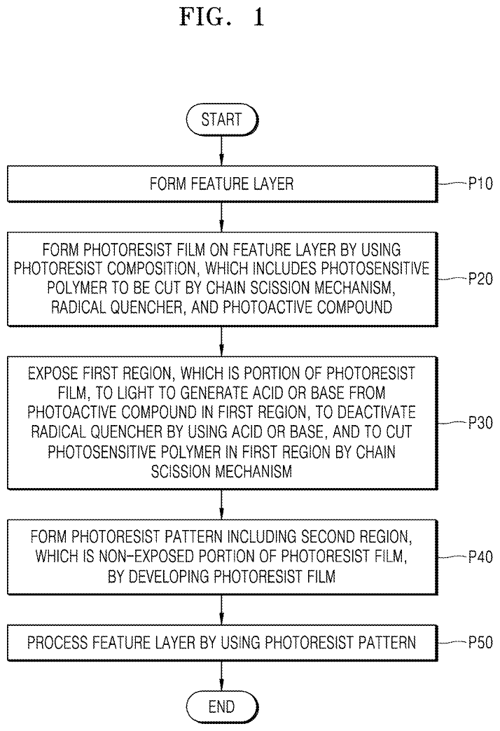

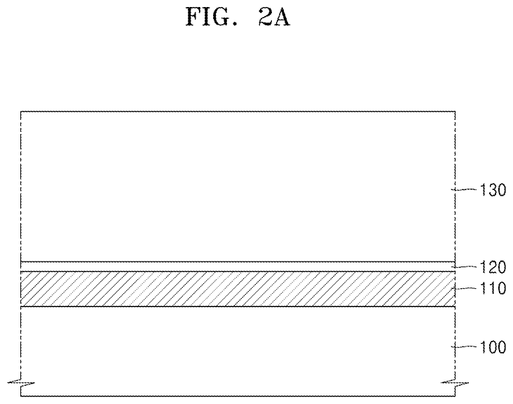

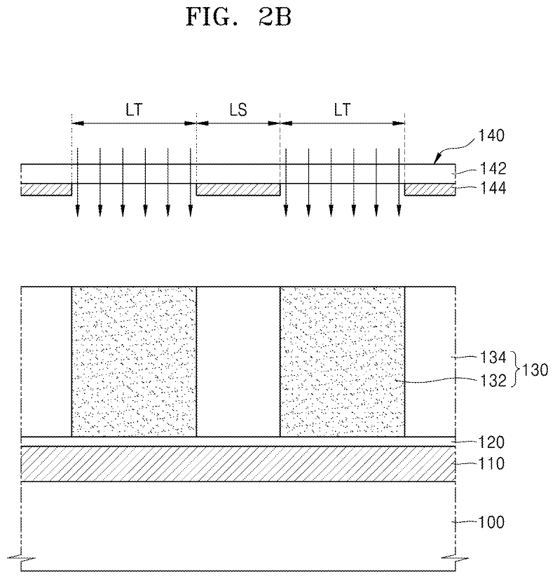

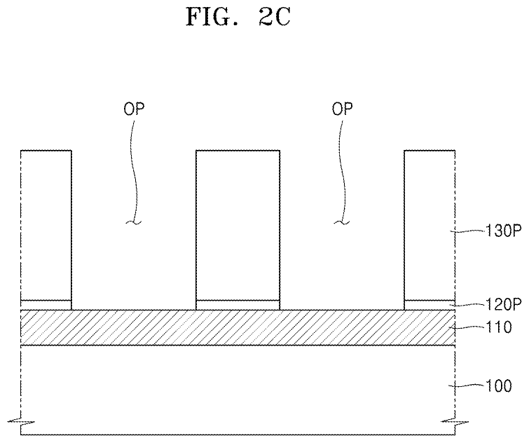

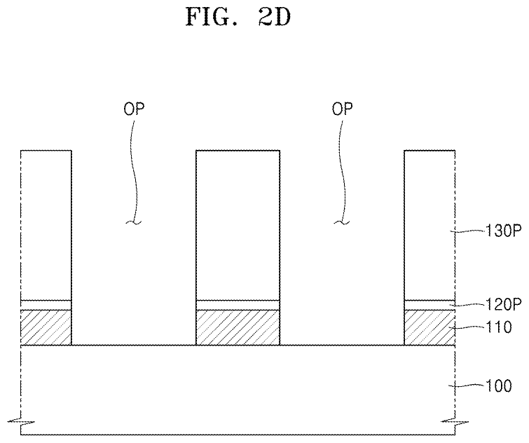

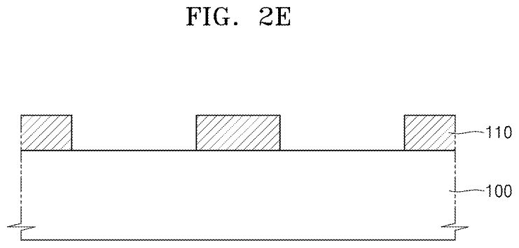

FIG. 1 is a flowchart illustrating a method of manufacturing an integrated circuit device, according to an embodiment. FIGS. 2A to 2E are cross-sectional views respectively illustrating operations of a method of manufacturing an integrated circuit device, according to an embodiment.

Referring to FIGS. 1 and 2A, a feature layer 110 may be formed on a substrate 100 (P10), and a photoresist film 130 may be formed on the feature layer 110 by using the photoresist composition according to an embodiment.

The photoresist film 130 may include the photosensitive polymer, the radical quencher, and the PAC, which are components of the photoresist composition. A more detailed configuration of the photoresist composition is the same as described above.

The substrate 100 may be or include a semiconductor substrate. For example, the substrate 100 may include a semiconductor material, such as Si or Ge, or a compound semiconductor material, such as SiGe, SiC, GaAs, InAs, or InP. The feature layer 110 may include an insulating film, a conductive film, or a semiconductor film. For example, the feature layer 110 may include, as non-limiting examples, a metal, an alloy, a metal carbide, a metal nitride, a metal oxynitride, a metal oxycarbide, a semiconductor, polysilicon, an oxide, a nitride, an oxynitride, or a combination thereof.

In an embodiment, as shown in FIG. 2A, a lower film 120 may be formed on the feature layer 110. In this case, the photoresist film 130 may be formed on the lower film 120. The lower film 120 may prevent adverse effects that might be exerted on the photoresist film 130 by the feature layer 110 under the photoresist film 130. In an embodiment, the lower film 120 may include an organic or inorganic anti-reflective coating (ARC) material for a KrF excimer laser, an ArF excimer laser, an extreme ultraviolet (EUV) laser, or any other light source. In an embodiment, the lower film 120 may include a bottom anti-reflective coating (BARC) film or a developable bottom anti-reflective coating (DBARC) film. In an embodiment, the lower film 120 may include an organic component having a light-absorption structure. The light-absorption structure may include, for example, a hydrocarbon compound having a structure in which one or more benzene rings are fused. The lower film 120 may have a thickness of about 1 nm to about 100 nm, as non-limiting examples. In some embodiments, the lower film 120 may be omitted.

To form the photoresist film 130, the photoresist composition according to an embodiment may be coated onto the lower film 120. The coating may be performed by a method such as spin coating, spray coating, or dip coating. The thickness of the photoresist film 130 may be several to hundreds of times the thickness of the lower film 120. The photoresist film 130 may have a thickness of about 10 nm to about 1 μm, as non-limiting examples.

In an embodiment, the photoresist composition coated on the lower film 120 may be heat-treated. The process of heat-treating the photoresist composition may be performed at a temperature of about 60° C. to about 300° C. for about 10 seconds to about 100 seconds, as non-limiting examples.

Referring to FIGS. 1 and 2B, by exposing a first region 132, which is a portion of the photoresist film 130, to light, the photosensitive polymer in the first region 132 may be cut by a chain scission mechanism. An acid or base may be generated from the PAC in the first region 132, and the radical quencher in the first region 132 may be deactivated by using the acid or the base (P30).

During the exposure of the photoresist film 130 to light according to process P30 of FIG. 1, in the exposed region, that is, the first region 132, radical intermediates may be generated from the photosensitive polymer due to light absorption of the photosensitive polymer of the photoresist film 130. The photosensitive polymer may be cut by the radical intermediates and thus the molecular weight thereof may be reduced. Therefore, a difference in solubility in a developer between the exposed region, that is, the first region 132, and a non-exposed region, that is, a second region 134, of the photoresist film 130 may be increased.

In the exposed region, that is, in the first region 132 of the photoresist film 130, an acid or a base may be generated from the PAC. For example, when the PAC includes a photobase generator, the base may be generated from the PAC. When the PAC includes a photoacid generator, acid may be generated from the PAC.

When the radical quencher includes a phenol-based compound and the PAC includes a photobase generator, a deprotonation reaction, in which a proton (hydrogen cation, H⁺) is removed from the radical quencher, may occur in the first region 132 through an acid-base reaction between the radical quencher and the base generated from the photobase generator. As a result, a proton may be released from a hydroxyl functional group (—OH), which is included in the radical quencher. Therefore, in the first region 132, the radical quencher may be present in a deactivated state including an anionic oxygen atom.

When the radical quencher includes a phenol-based compound and the PAC includes a photoacid generator, a protonation reaction, in which a proton is added to the radical quencher, may occur in the first region 132 through an acid-base reaction between the radical quencher and the acid generated from the photoacid generator. As a result, a hydrogen atom may be added to a hydroxyl functional group (—OH) that is included in the radical quencher. Therefore, in the first region 132, the radical quencher may be present in a deactivated state including an oxonium ion.

When the radical quencher includes an amine-based compound and the PAC includes a photoacid generator, a protonation reaction, in which a proton is added to the radical quencher, may occur in the first region 132 through an acid-base reaction between the radical quencher and the acid generated from the photoacid generator. As a result, a proton may be added to an amine functional group (—NH), which is included in the radical quencher. Therefore, in the first region 132, the radical quencher may be present in a deactivated state including an ammonium ion.

In the non-exposed region, that is, in the second region 134, of the photoresist film 130, because acid or base is not generated from the PAC, a deprotonation reaction or a protonation reaction of the radical quencher may not be performed in the second region 134. Therefore, in the second region 134, the radical quencher may be maintained in a state including a hydroxyl functional group (—OH) or an amine functional group (—NH). Therefore, in the second region 134, the radical quencher may be present in an activated state such that the radical quencher may capture radicals.

Therefore, even when radical intermediates generated in the exposed region, that is, in the first region 132, of the photoresist film 130 are introduced from the first region 132 into the non-exposed region, that is, into the second region 134, by diffusion, the radical intermediates introduced into the second region 134 may be captured by the radical quencher in the second region 134, thereby preventing the photosensitive polymer from being cut by a chain scission mechanism. Therefore, the photosensitive polymer may be selectively cut only in the first region 132, which is an exposed portion of the photoresist film 130, and may not be cut in the second region 134, which is a non-exposed portion of the photoresist film 130. Accordingly, a difference in solubility in a developer between the first region 132 and the second region 134 of the photoresist film 130 may be increased.

In some embodiments, to expose the first region 132 of the photoresist film 130 to light, a photomask 140 that has a plurality of light-shielding areas LS and a plurality of light-transmitting areas LT may be aligned at a certain position above the photoresist film 130. The first region 132 of the photoresist film 130 may be exposed to light through the plurality of light-transmitting areas LT of the photomask 140. To expose the first region 132 of the photoresist film 130 to light, a KrF excimer laser (248 nm), an ArF excimer laser (193 nm), an F₂ excimer laser (157 nm), an EUV laser (13.5 nm), or an electron beam may be used.

The photomask 140 may include a transparent substrate 142 and a plurality of light-shielding patterns 144 formed on the transparent substrate 142 in the plurality of light-shielding areas LS. The transparent substrate 142 may include quartz. The plurality of light-shielding patterns 144 may include chromium (Cr). The plurality of light-transmitting areas LT may be defined by the plurality of light-shielding patterns 144. In an embodiment, to expose the first region 132 of the photoresist film 130 to light, a reflective photomask (not shown) for EUV exposure may be used instead of the photomask 140.

After the first region 132 of the photoresist film 130 is exposed to light according to process P30 of FIG. 1, the photoresist film 130 may undergo annealing. The annealing may be performed at a temperature of about 50° C. to about 400° C. for about 10 seconds to about 100 seconds, as non-limiting examples. In an embodiment, during the annealing of the photoresist film 130, the photosensitive polymer in the first region 132 may be cut more easily. Accordingly, the difference in solubility of the developer between the exposed region, that is, the first region 132, and the non-exposed region, that is, the second region 134, of the photoresist film 130 may be further increased. Therefore, a final pattern intended to be formed in the feature layer 110 in a subsequent process may exhibit reduced line edge roughness (LER) or line width roughness (LWR), thereby obtaining high pattern fidelity.

Referring to FIGS. 1 and 2C, the first region 132 of the photoresist film 130 may be removed by developing the photoresist film 130 by using a developer. As a result, a photoresist pattern 130P, which includes the non-exposed region, that is, the second region 134, of the photoresist film 130, may be formed (P40).

The photoresist pattern 130P may include a plurality of openings OP. After the photoresist pattern 130P is formed, a lower pattern 120P may be formed by removing portions of the lower film 120 that are exposed by the plurality of openings OP.

In an embodiment, the development of the photoresist film 130 may be performed by a positive-tone development (PTD) process. In this case, the developer may include tetramethylammonium hydroxide (TMAH), 2-propanol, toluene, water, or the like, as non-limiting examples, depending on the type of the photosensitive polymer in the photoresist composition.

As described with reference to FIG. 2B, as the difference in solubility in the developer between the exposed region, that is, the first region 132, and the non-exposed region, that is, the second region 134, of the photoresist film 130 increases, the second region 134 may remain without being removed during the removal of the first region 132 through the development of the photoresist film 130 in the process of FIG. 2C. Therefore, after the photoresist film 130 is developed, residual defects, such as footing, may not be generated and a vertical sidewall profile of the photoresist pattern 130P may be obtained. As such, because the profile of the photoresist pattern 130P improves when the feature layer 110 is processed by using the photoresist pattern 130P, the CD of an intended processing region in the feature layer 110 may be precisely controlled.

Referring to FIGS. 1 and 2D, the feature layer 110 may be processed by using the photoresist pattern 130P (P50).

To process the feature layer 110, various processes, such as a process of etching the feature layer 110 exposed by the openings OP of the photoresist pattern 130P, a process of implanting impurity ions into the feature layer 110, a process of forming an additional film on the feature layer 110 through the openings OP, and a process of modifying portions of the feature layer 110 through the openings OP, may be performed. As an exemplary process of processing the feature layer 110, FIG. 2D illustrates an example of forming a feature pattern 110P by etching the feature layer 110 exposed by the openings OP.

In some embodiments, the process of forming the feature layer 110 may be omitted from the process described with reference to FIG. 2A. In this case, instead of performing the process described with reference to FIG. 2D and process P50 of FIG. 1, the substrate 100 may be processed by using the photoresist pattern 130P. For example, various processes, such as a process of etching portions of the substrate 100, a process of implanting impurity ions into portions of the substrate 100, a process of forming an additional film on the substrate 100 through the openings OP, and a process of modifying portions of the substrate 100 through the openings OP, may be performed by using the photoresist pattern 130P.

Referring to FIG. 2E, in the resulting product of FIG. 2D, the photoresist pattern 130P and the lower pattern 120P that remain on the feature pattern 110P may be removed. To remove the photoresist pattern 130P and the lower pattern 120P, ashing and strip processes may be used.

According to the method of manufacturing an integrated circuit device, which is described with reference to FIGS. 1 and 2A to 2E, according to an embodiment, a difference in solubility in a developer between an exposed region and a non-exposed region of the photoresist film 130, which is obtained from the photoresist composition according to embodiments, may be increased, and thus, the contrast therebetween may be increased. Accordingly, the photoresist pattern 130P obtained from the photoresist film 130 may exhibit reduced LER and LWR, thereby providing high pattern fidelity. Therefore, when a subsequent process is performed on the feature layer 110 and/or the substrate 100 by using the photoresist pattern 130P, CDs of processing regions or patterns intended to be formed in the feature layer 110 and/or the substrate 100 may be precisely controlled, thereby improving dimensional accuracy. In addition, a CD distribution of patterns intended to be implemented on the substrate 100 may be uniformly controlled and the productivity of a manufacturing process of an integrated circuit device may improve.

By way of summation and review, the photoresist composition according to an embodiment may be advantageously used to form a pattern having a relatively high aspect ratio. For example, the photoresist composition according to an embodiment may be advantageously used for a photolithography process for forming a pattern having a fine width selected from a range of about 5 nm to about 100 nm

While concepts have been particularly shown and described with reference to embodiments thereof, it will be understood that various changes in form and details may be made therein without departing from the spirit and scope of the following claims.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoresist composition, comprising:
a photosensitive polymer that can be cut by a chain scission mechanism due to light;
a radical quencher including a phenol-based compound; and
a photoactive compound (PAC).

2. The photoresist composition as claimed in claim 1, wherein the radical quencher includes at least one electron-donating group selected from an alkyl group, an alkenyl group, an alkynyl group, an aryl group, and an arylalkyl group.

3. The photoresist composition as claimed in claim 1, wherein the radical quencher includes a monophenol compound.

4. The photoresist composition as claimed in claim 1, wherein the radical quencher includes a polyphenol compound.

5. The photoresist composition as claimed in claim 1, wherein the phenol-based compound constituting the radical quencher includes a monomer.

6. The photoresist composition as claimed in claim 1, wherein the PAC includes a photobase generator.

7. The photoresist composition as claimed in claim 6, wherein the photobase generator includes one selected from an ionic photobase generator and a nonionic photobase generator.

8. The photoresist composition as claimed in claim 1, wherein the PAC includes a photoacid generator.

9. The photoresist composition as claimed in claim 8, wherein the photoacid generator includes one selected from an ionic photoacid generator and a nonionic photoacid generator.

10. The photoresist composition as claimed in claim 1, wherein the radical quencher is present in an amount of about 5 wt % to about 50 wt % based on a total weight of the photosensitive polymer, and the PAC is present in an amount of about 1 to about 1.5 times the amount of the radical quencher.

11. A photoresist composition comprising:
a photosensitive polymer to be cut by a chain scission mechanism due to light;
a radical quencher including an amine-based compound; and
a photoacid generator.

12. The photoresist composition as claimed in claim 11, wherein the radical quencher includes at least one electron-donating group selected from an aryl group and an arylalkyl group.

13. The photoresist composition as claimed in claim 11, wherein the amine-based compound constituting the radical quencher includes a monomer.

14. The photoresist composition as claimed in claim 11, wherein the amine-based compound has the following formula:
(where R⁶ and R⁷ are each independently a C6 to C18 aryl group or a C6 to C18 arylalkyl group).

15. The photoresist composition as claimed in claim 11, wherein the photoacid generator includes one selected from an ionic photoacid generator and a nonionic photoacid generator.

16. The photoresist composition as claimed in claim 11, wherein the radical quencher is present in an amount of about 5 wt % to about 50 wt % based on a total weight of the photosensitive polymer, and the photoacid generator is present in an amount of about 1 to about 1.5 times the amount of the radical quencher.

17. A method of manufacturing an integrated circuit device, the method comprising:
forming a photoresist film on a lower film by using a photoresist composition that includes a photosensitive polymer, a radical quencher, and a photoactive compound (PAC);
exposing a first region, which is a portion of the photoresist film, to light to generate acid or base from the PAC in the first region, to deactivate the radical quencher by using the acid or the base, and to cut the photosensitive polymer in the first region by a chain scission mechanism;
forming a photoresist pattern by developing the photoresist film, the photoresist pattern including a second region that is a non-exposed portion of the photoresist film; and
processing the lower film by using the photoresist pattern.

18. The method as claimed in claim 17, wherein the radical quencher includes a phenol-based compound, and the PAC include one selected from a photobase generator and a photoacid generator.

19. The method as claimed in claim 17, wherein the radical quencher includes an amine-based compound, and the PAC includes a photoacid generator.

20. The method as claimed in claim 17, wherein, in the exposing of the first region to light, the first region is exposed to light by using a KrF excimer laser (248 nm), an ArF excimer laser (193 nm), an F₂ excimer laser (157 nm), an extreme ultraviolet (EUV) laser (13.5 nm), or an electron beam.
